(19) United States
(12) Patent Application Publication
(10) Pub. No.: US 2009/0035946 A1
(43) Pub. Date: Feb. 5, 2009

(54) IN SITU DEPOSITION OF DIFFERENT METAL-CONTAINING FILMS USING CYCLOPENTADIENYL METAL PRECURSORS

(75) Inventors: Dieter Pierreux, Dilbeek (BE); Bert Jongbloed, Ureterp (NL); Peter Zagwijn, Nijkerk (NL)

Correspondence Address: KNOBBE MARTENS OLSON & BEAR LLP, 2040 MAIN STREET, FOURTEENTH FLOOR, IRVINE, CA, 92614, US

(73) Assignee: ASM INTERNATIONAL N.V.

(21) Appl. No.: 12/173,374

(22) Filed: Jul. 15, 2008

Related U.S. Application Data
(60) Provisional application No. 60/953,132, filed on Jul. 31, 2007.

(51) Int. Cl. H01L 21/31; C23C 16/06

(52) U.S. Cl. 438/763; 118/715; 257/E21.24

(57) ABSTRACT

A method is disclosed depositing multiple layers of different materials in a sequential process within a deposition chamber. A substrate is provided in a deposition chamber. A plurality of cycles of a first atomic layer deposition (ALD) process is sequentially conducted to deposit a layer of a first material on the substrate in the deposition chamber. These first cycles include pulsing a cyclopentadienyl metal precursor. A plurality of cycles of a second ALD process is sequentially conducted to deposit a layer of a second material on the layer of the first material in the deposition chamber. The second material comprises a metal different from the metal in the cyclopentadienyl metal precursor.

### CLAIM FOR PRIORITY

The present application claims priority to Provisional Patent Application No. 60/953,132, filed Jul. 31, 2007.

### INCORPORATION BY REFERENCE

The present application incorporates by reference the entire disclosures of PCT Patent Application Publication No. WO 2006/131751 A1; U.S. Patent Application Publication No. US 2004/0250853 A1; U.S. Pat. No. 6,746,240; U.S. Patent Application Publication No. US 2003/0111013 A1; U.S. Patent Application Publication No. US 2008/0081112 A1; and Provisional Patent Application No. 60/953,132, filed Jul. 31, 2007.

### BACKGROUND OF THE INVENTION

1. Field of the Invention

The present application relates generally to semiconductor processing, and more particularly to atomic layer deposition of metal-containing layers.

2. Description of the Related Art

High-temperature ovens, called reactors, are used to create structures of very fine dimensions, such as integrated circuits on semiconductor substrates. One or more substrates, such as silicon wafers, are placed on a substrate support inside the reaction chamber. Both the substrate and support are heated to a desired temperature. In a typical substrate treatment step, reactant gases (including precursors) are passed over the heated substrate, causing the deposition (e.g., chemical vapor deposition, or CVD) of a thin layer on the substrate. CVD is typically conducted at temperatures high enough to react or decompose the precursors and leave the desired elements in a film on the substrate.

Deposition equipment normally includes a system for delivering gas to the reaction chamber. The gas delivery system typically comprises a plurality of reactant vapor sources, optionally one carrier gas and/or purge gas source, a network of pipes for delivering the reactant gases to the reaction chamber, eventually an injection manifold or showerhead for injecting the gas evenly into the chamber, and a number of valves for controlling the gas flow. Some reactant vapor sources may be in powder or liquid form, and means for vaporizing such reactants can be provided (e.g., bubblers).

Another type of deposition process is atomic layer deposition (ALD). In ALD, two or more mutually reactive reactants are alternately introduced into the reaction chamber. Typically, one of the reactants will adsorb onto the substrate surface, but it cannot completely decompose without reaction with another reactant. The first reactant adsorbs until it saturates the substrate surface; further growth cannot occur until the second reactant is introduced. Thus, the film thickness is controlled by the number of reactant injection cycles rather than the deposition time, as is the case for conventional CVD processes. In contrast to CVD, ALD is said to be self-limiting or self-saturating, since each cycle leaves no more than about a molecular monolayer. Accordingly, ALD allows for extremely precise control of film thickness and uniformity. Thermal ALD is typically conducted at temperatures in a range 200-500° C., while plasma processes can employ significantly lower temperatures.

In ALD, the reaction chamber is typically pulsed with a non-reactive protective gas between injections of different reactant gases, to rid the chamber of any excess of the preceding reactant gas. Otherwise, the excess preceding reactant would intermix and react with the subsequently pulsed reactant to form unwanted CVD-type growth on the substrate surface and/or on surfaces of the chamber.

There are numerous applications for zirconium- and hafnium-containing materials in the fabrication of integrated circuits. Such materials include zirconium oxide (ZrOₓ, such as ZrO₂), hafnium oxide (HfOₓ, such as HfO₂), zirconium silicate (ZrSiₓO_{y}), hafnium silicate (HfSiₓO_{y}), zirconium nitride (ZrN), and hafnium nitride (HfN). Exemplary applications include use as a dielectric in electrical devices, such as capacitors and transistors. As used herein, “Zr/Hf” refers to zirconium and/or hafnium, and “Zr/Hf oxide” refers to zirconium oxide and/or hafnium oxide.

The properties of Zr/Hf oxide, however, are closely dependent on processing and deposition parameters. Thus, the suitability and desirability of deposited Zr/Hf oxide for a particular application can depend on the availability of a deposition process able to form Zr/Hf oxide with desired properties, e.g., uniform thickness, composition, crystallinity and electrical properties, such as high dielectric constant. As a result, research into the development of new Zr/Hf deposition processes is ongoing. Recently, TiN/ZrO₂/Al₂O₃/ZrO₂/TiN dielectric films were successfully demonstrated to be applicable to 45 nm DRAM devices.

### SUMMARY

In one aspect, the present application discloses a method of depositing multiple layers of different materials in a sequential process within a deposition chamber. A substrate is provided in a deposition chamber. A plurality of cycles of a first atomic layer deposition (ALD) process is sequentially conducted to deposit a layer of a first material on the substrate in the deposition chamber. These first cycles include pulsing a cyclopentadienyl metal precursor. A plurality of cycles of a second ALD process is sequentially conducted to deposit a layer of a second material on the layer of the first material in the deposition chamber. The second material comprises a metal different from the metal in the cyclopentadienyl metal precursor.

In another aspect, the present application discloses an apparatus comprising a processing chamber, a cyclopentadienyl metal precursor source, an oxygen precursor source, an aluminum precursor source, and a deposition control system. The processing chamber is configured to contain a plurality of substrates. The cyclopentadienyl metal precursor source is connected to the chamber to deliver a vapor of the cyclopentadienyl metal precursor into the chamber. The oxygen precursor source is connected to the chamber to deliver a vapor of the oxygen precursor into the chamber. The aluminum precursor source is connected to the chamber to deliver a vapor of the aluminum precursor into the chamber. The deposition control system is configured to conduct ALD in the chamber of a metal oxide from the cyclopentadienyl metal precursor and the oxygen precursor. The deposition control system is also configured to conduct ALD in the chamber of aluminum oxide from the aluminum precursor and the oxygen precursor.

For purposes of summarizing the present application and the advantages achieved over the prior art, certain objects and advantages have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these embodiments are intended to be within the scope of the invention. These and other embodiments of the present invention will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

The claimed methods and apparatuses will be better understood from the Detailed Description of the Preferred Embodiments and from the appended drawings, which are meant to illustrate and not to limit the claims, and wherein:

FIG. 1 is a flow chart of a conventional method of ZrO₂/Al₂O₃/ZrO₂ deposition.

FIG. 2 is a flow chart illustrating a method of in situ deposition of two thin films onto a substrate in the same reactor in accordance with one embodiment.

FIG. 3 is a flow chart illustrating a method of depositing two films in situ using a cyclopentadienyl metal precursor in accordance with a more particular embodiment.

FIG. 4 is a flow chart illustrating one embodiment of a method of ZrOₓ/AlOₓ/ZrOₓ deposition.

FIG. 5 illustrates an exemplary stack of films (ZrO₂ or HfO₂)/Al₂O₃/(ZrO₂ or HfO₂)/TiN on silicon.

FIG. 6 is a flow chart illustrating a method of in situ deposition of Zr/Hf oxide and aluminum oxide onto substrates within a single reactor.

FIG. 7 illustrates an exemplary furnace for use with embodiments of the invention.

FIG. 8 illustrates an exemplary vapor delivery system for use with embodiments of the invention.

FIG. 9 illustrates another exemplary furnace for use with embodiments of the invention.

FIG. 10 illustrates an additional exemplary furnace for use with embodiments of the invention.

FIG. 11 is a schematic cross-sectional side view of an elongated batch process tube with a gas injector, constructed in accordance with one embodiment of the invention.

FIG. 12 is a front view of a gas injector for use with the batch process tube of FIG. 11.

FIG. 13 is a schematic illustration of an embodiment of a deposition control system.

### DETAILED DESCRIPTION OF THE PREFERRED EMBODIMENTS

### Overview

Zirconium oxide (ZrOₓ) films with high dielectric constant (k) can be deposited in batch systems with alkyl amide precursors. Thermal decomposition of these precursors limits the process temperature, typically to less than about 250° C. The same is true for hafnium oxide (HfOₓ) deposition. Low temperature deposition is often considered a benefit of ALD, since it can preserve thermal budgets for sensitive integrated circuit substrates. In contrast, it is generally preferred to deposit aluminum oxide (AlOₓ, such as Al₂O₃) at higher temperatures (e.g., greater than 300° C., such as 350° C.) to optimize electrical film quality. Because Zr/Hf oxide deposition and aluminum oxide deposition have conventionally been conducted at different temperatures, particularly by ALD, stacks including Zr/Hf oxide and aluminum oxide, such as ZrOₓ/AlOₓ/ZrOₓ (ZAZ), could not be created in situ at the same temperature in the same reactor.

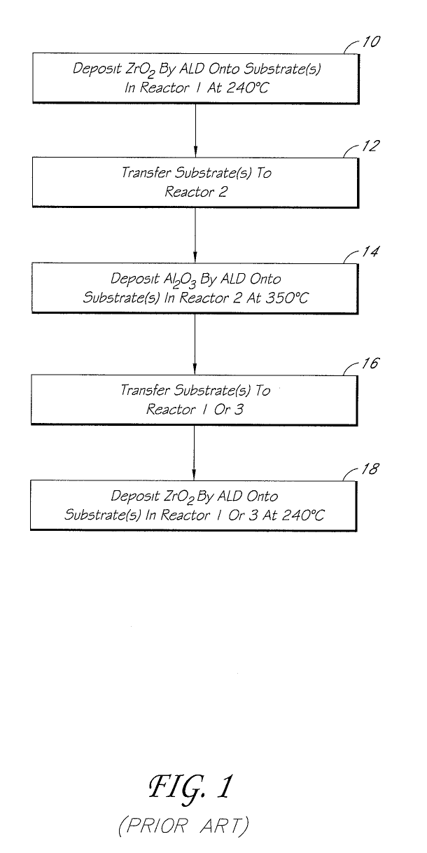

For example, one method of depositing ZAZ stacks is illustrated in FIG. 1. In step 10, zirconium oxide is formed on one or more substrates in a first reactor, Reactor 1. Typically, the film is formed by ALD using alkyl amide precursors, such as tetraethyl methylamino zirconium (TEMAZ), and an oxygen precursor such as O₃, O₂, or H₂O. Since the alkyl amide precursor decomposes at higher temperatures (e.g., temperatures greater than 250° C.), the temperature in Reactor 1 during step 10 should be maintained below the thermal decomposition temperature. For example, the temperature of Reactor 1 during step 10 is typically less than 250° C., such as 240° C. After the zirconium oxide film is formed, the substrates are transferred 12 to a second reactor, Reactor 2, for deposition of aluminum oxide in step 14, such as by ALD using precursors trimethyl aluminum (TMA) and an oxygen precursor (O₃, O₂, or H₂O). Once the aluminum oxide is formed, the substrates can be transferred 16 back to Reactor 1 or to a third Reactor 3 for further deposition of zirconium oxide in step 18, again at a lower temperature such as 240° C.

Thus, deposition of adjacent layers of ZrOₓ and AlOₓ using the process of FIG. 1 involves the use of two reactors, a zirconium oxide deposition reactor and an aluminum oxide deposition reactor. Deposition of adjacent layers of HfOₓ and AlOₓ using this process also involves two reactors, wherein the HfOₓ deposition typically employs precursors such as hafnium methylethylamide (Hf(NEtMe)₄) and oxygen, and ALD at temperatures less than the thermal decomposition temperature of the Hf(NEtMe)₄ precursor.

One reason why Zr/Hf oxide and aluminum oxide are deposited in FIG. 1 in separate reactors, as opposed to depositing both layers at different temperatures within the same reactor, is that it takes longer to wait for the temperature to change and stabilize throughout the chamber (particularly for a batch reactor) than it takes to transfer the one or more substrates to another chamber maintained at a different temperature. At the relatively low temperatures used for conventional Zr/Hf oxide deposition, heat transport through radiation is limited. Heat transport by conduction is also not very efficient for a stack of substrates in a batch furnace at low pressure. Consequently, temperature stabilization is slow, and it is often less time consuming to transfer the substrates to another chamber rather than change the temperature in the original chamber. Moreover, even if time of temperature ramping were not a deterrent, depositing multiple different materials in the same batch reactor results in different coefficients of thermal expansion (CTE) for coatings on reactor parts and substrates, which can then lead to flaking when the temperatures are changed between depositions.

In these conventional methods, the need to transfer substrates between two separate reactors involves greater equipment costs and more complicated processing, and results in lower throughput. Furthermore, while transferring the substrate with Zr/Hf oxide film from the Zr/Hf oxide deposition reactor to an aluminum oxide deposition reactor, the Zr/Hf oxide becomes exposed to air, which could lead to undesirable contamination within the dielectric stack. Embodiments of the present invention include methods of depositing different ALD films (such as ZAZ stacks or HfOₓ/AlOₓ/HfOₓ stacks) in the same reactor at substantially the same temperature so as to avoid the drawbacks associated with depositing films in different reactors as discussed above.

A recent PCT Patent Application Publication, WO 2006/131751 A1 to Heys et al. (the “Heys publication”), recognizes that certain cyclopentadienyl Zr/Hf precursors allow the deposition of Zr/Hf oxide films with good uniformity at higher temperatures (e.g., between 300-500° C.). Generally, aluminum oxide film growth is carried out with TMA and oxygen at a temperature greater than about 300° C. to optimize electrical film quality. Deposition of Zr/Hf oxide at high temperatures using cyclopentadienyl Zr/Hf precursors is advantageously compatible with conventional aluminum oxide deposition. In other words, the ability of cyclopentadienyl Zr/Hf precursors to deposit ZrOₓ or HfOₓ films at higher temperatures makes it possible to deposit Zr/Hf oxide and aluminum oxide in situ at substantially the same temperature. Consequently, embodiments of the invention combine the cyclopentadienyl Zr/Hf precursors (used for deposition at high temperatures) and sequential ALD processing to achieve in situ deposition of Zr/Hf oxide and aluminum oxide onto one or more substrates in a single reactor.

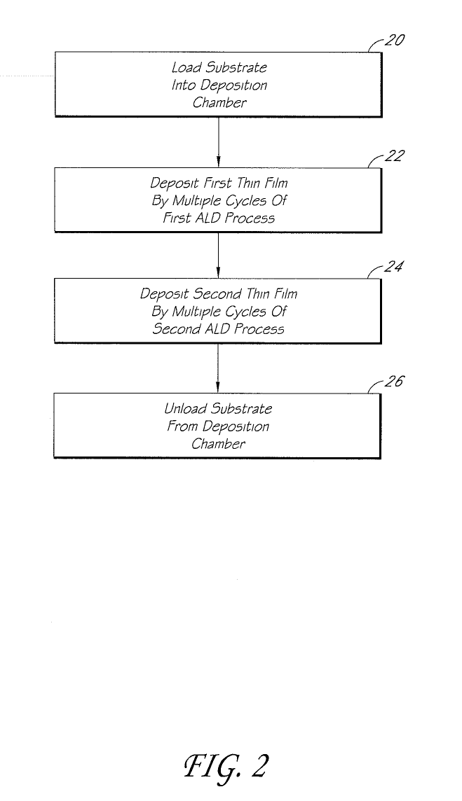

More generally, the present application discloses depositing two films by ALD in situ in the same deposition chamber. With reference to FIG. 2, at least one substrate can be loaded 20 into a deposition chamber (preferably a batch reactor, but a single substrate reaction chamber is also possible), and then a first thin film can be deposited 22 onto the substrate by multiple cycles of a first ALD process. Subsequently, in the same deposition chamber, a second thin film can be deposited 24 onto the substrate by multiple cycles of a second ALD process. Finally, the substrate is unloaded 26 from the deposition chamber.

“Substrate” is used herein in its usual sense to include any underlying surface onto which a material is deposited or applied. Preferred substrates include semiconductor wafers, such as silicon wafers of various sizes, including industry standard 200 mm and 300 mm wafers. However, substrates can be made of virtually any material, including without limitation metal, silicon, germanium, plastic, and/or glass, preferably silicon compounds (including Si—O—C—H low dielectric constant films) and silicon alloys. Substrates can also have in them physical structures such as trenches or steps, as in a partially fabricated integrated circuit.

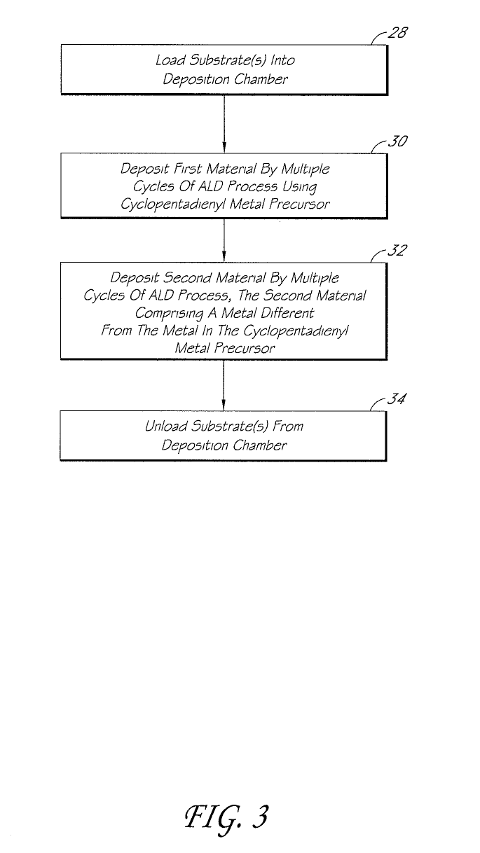

In certain embodiments, the present application discloses viable methods for in situ ALD of a first material using a cyclopentadienyl metal precursor, and ALD of a second material with a different metal. FIG. 3 illustrates an embodiment. First, at least one substrate is loaded 28 into a deposition chamber of a reactor. The reactor is preferably a batch reactor, but the process can alternatively be conducted in a single substrate reaction chamber. Next, the first material is deposited 30 onto the substrate by multiple cycles of an ALD process using a cyclopentadienyl metal precursor. Then, the second material is deposited 32 onto the substrate in the same chamber, without removing the substrate from the deposition chamber between said depositing steps 30 and 32. The second material comprises a metal different from the metal in the cyclopentadienyl metal precursor. The substrate is then unloaded 34 from the deposition chamber. The cycles of the first ALD process 30 are conducted at a first average temperature and the cycles of the second ALD process 32 are conducted at a second average temperature. The first and second average temperatures are preferably within about 25° C., more preferably within about 10° C., and even more preferably within about 5° C. of one another.

Such a process is useful for depositing stacks of two or more thin layers in semiconductor processing, particularly oxides. For example, U.S. Pat. No. 6,660,660 teaches depositing thin layer stacks by ALD, including adjacent high k dielectric layers and “interface layers,” such as aluminum oxide or rare earth oxides. Examples of such stacks include AlOₓ/high k layer/AlOₓ, and rare earth oxide/high k layer/rare earth oxide. Another example is the ZAZ stack discussed elsewhere herein.

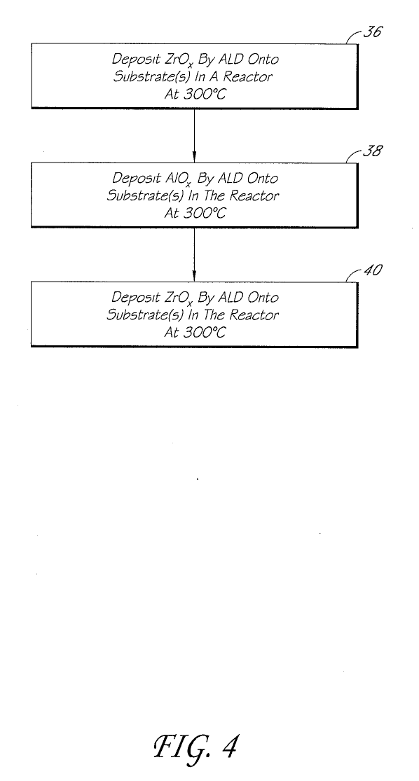

As noted above, in certain embodiments the present application provides viable methods for in situ deposition of zirconium- and hafnium-containing materials (such as zirconium oxide, hafnium oxide, zirconium silicate, hafnium silicate, zirconium nitride, and hafnium nitride) and aluminum-containing materials (such as aluminum oxide) onto one or more substrates in a single reactor, preferably at substantially the same temperature. For example, FIG. 4 illustrates an embodiment of a method of depositing ZAZ stacks. At least one substrate is initially loaded into a chamber of a reactor. The reactor is preferably a batch reactor, but the process can alternatively be conducted in a single substrate reaction chamber. In step 36, a ZrOₓ film (such as ZrO₂) is deposited by ALD onto the substrate in the reactor at a certain temperature, such as about 300° C. In step 38, an AlOₓ film (such as Al₂O₃) is deposited by ALD onto the substrate in the reactor at substantially the same temperature, directly onto the ZrOₓ film. In step 40, another ZrOₓ film (such as ZrO₂) is deposited by ALD onto the substrate in the reactor at substantially the same temperature, directly onto the AlOₓ film. Skilled artisans will appreciate that this method can be used alternatively for the deposition of HfOₓ/AlOₓ/HfOₓ stacks.

As recognized by the Heys publication, certain cyclopentadienyl metal precursors permit the deposition of zirconium- and hafnium-containing materials at relatively high temperatures. Some cyclopentadienyl metal precursors have the general formula (R⁶ₓCp₂MR⁴OR⁵), where Cp represents a cyclopentadienyl ligand, R⁴ is selected from an alkyl group and an alkoxy group, R⁵ is an alkyl group, x is 0 or an integer of 1-5, R⁶ is a substituting alkyl group, alkoxy group or amido group of the Cp ligand wherein each R⁶ group can be selected independently, and M is a metal. Preferably, the R⁴ and R⁵ ligands have 1-4 carbon atoms, especially 1 or 2, ideally 1. R⁶ is preferably H or an alkyl group having 1 or 2 carbon atoms, especially a methyl group. One particular precursor, in which R⁴ is an alkoxide group, has the formula (MeCp)₂M(OMe)₂, where Me is a methyl group, Cp is a cyclopentadienyl group, OMe is a methoxy group, and M is a metal. Where M is hafnium, the precursor is referred to as bis(methylcyclopentadienyl)bis(methoxy) hafnium (IV). Where M is zirconium, the precursor is referred to as bis(methylcyclopentadienyl)bis(methoxy) zirconium (IV). Another precursor has the formula (MeCp)₂M(OMe)Me. Where M is hafnium, the precursor is referred to as bis(methylcyclopentadienyl)methyl methoxy hafnium (IV). Where M is zirconium, the precursor is referred to as bis(methylcyclopentadienyl)methyl methoxy zirconium (IV). In preferred compounds, R⁶=Me and x=1. In other preferred compounds, x=0 with no further changes, resulting in the general formulas (Cp)₂M(OMe)₂, and (Cp)₂M(OMe)Me. When M is Zirconium, the precursors are referred to as bis(cyclopentadienyl)bis(methoxy) zirconium (IV) and as bis(cyclopentadienyl)methyl methoxy zirconium (IV). When M is Hafnium, the precursors are referred to as bis(cyclopentadienyl)bis(methoxy) hafnium (IV) and as bis(cyclopentadienyl)methyl methoxy hafnium (IV).

An advantage of these cyclopentadienyl metal precursors is that they allow for the deposition of certain metal-containing films, such as ZrOₓ and HfOₓ, at relatively higher temperatures, compared to the aforementioned conventional methods using alkyl amide precursors. This makes it possible to deposit these metal-containing films with other films (such as AlOₓ by use of trimethyl aluminum) in situ. In particular, these cyclopentadienyl metal precursors can be combined in an ALD process with an oxygen precursor (such as O₂, O₃, or H₂O) to deposit metal oxides at temperatures higher than the thermal decomposition temperatures of the alkyl amide precursors.

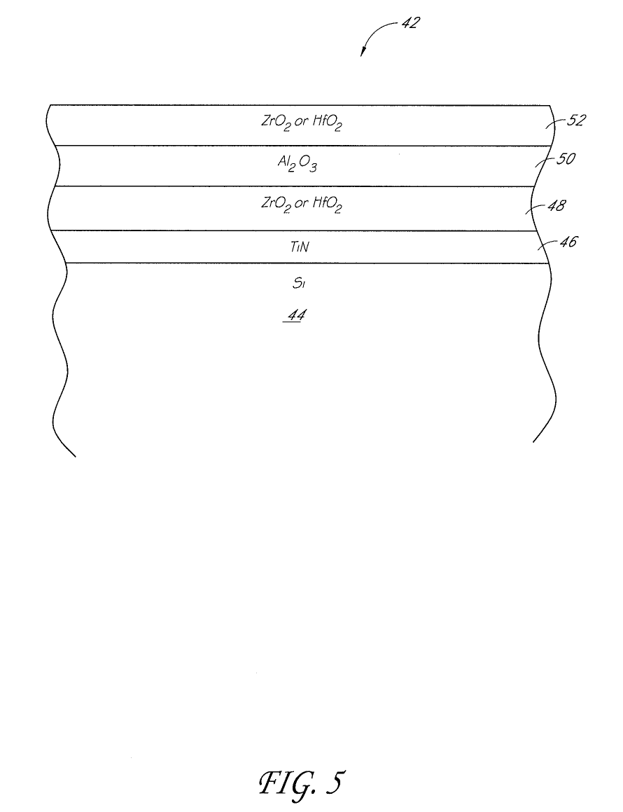

In one embodiment, cyclopentadienyl Zr/Hf precursors are used to create a film stack such as the stack 42 shown in FIG. 5. The illustrated stack 42 is formed on a silicon substrate 44. Optionally, a titanium nitride (TiN) layer may be deposited on the silicon 44 as a barrier to prevent interaction between high k dielectrics and the silicon substrate 44. The illustrated stack includes a layer 48 of ZrO₂ or HfO₂, a layer 50 of Al₂O₃ on the layer 48, and a layer 52 of ZrO₂ or HfO₂ on the layer 50.

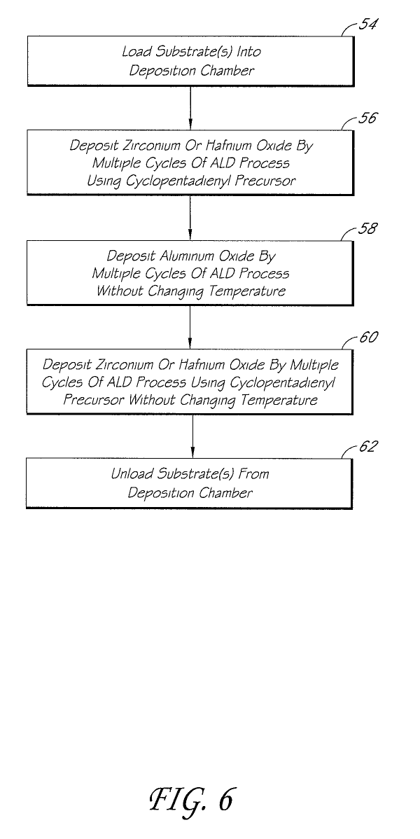

FIG. 6 illustrates an embodiment of a method of depositing layers of Zr/Hf oxide and aluminum oxide in situ at substantially the same temperature. This method can be used, e.g., to form the layers 48, 50, and 52 of the stack 42 of FIG. 5. Initially, at least one substrate is loaded 54 into a deposition chamber. The deposition chamber is preferably configured to process multiple substrates, but it can alternatively be a single substrate reaction chamber. Initially, one or more layers can be deposited, such as the TiN layer 46 as shown in FIG. 5. Next, ZrOₓ or HfOₓ (ZrO₂ or HfO₂ in the embodiment of FIG. 5) is deposited 56 onto the substrate, by multiple cycles of an ALD process using a cyclopentadienyl precursor. For example, ZrOₓ can be formed by pulsing ozone (or another suitable oxygen precursor) and either (MeCp)₂Zr(OMe)₂ or (MeCp)₂Zr(OMe)Me. Further, HfOₓ can be formed by pulsing ozone (or another suitable oxygen precursor) and either (MeCp)₂Hf(OMe)₂ or (MeCp)₂Hf(OMe)Me. This Zr/Hf oxide can form, e.g., the ZrO₂ or HfO₂ layer 48 of FIG. 5.

Typically, in each ALD process, both reactants are alternately pulsed into the reaction chamber, preferably with intermediate purge gas injections or chamber evacuation steps. In this method, each pair of reactant pulses comprises one cycle, and any number of cycles can be conducted. Of course, three or more reactant pulses can be present in each cycle, and not every reactant need serve as a precursor for an element left in the film. For example, in some cases a reactant may simply prepare a surface for a subsequent precursor pulse, such as by ligand gettering, hydroxylation or reduction. In some preferred embodiments, the targeted thicknesses of films are based on equivalent oxide thickness (EOT) and leakage requirements. For example, EOT of 6-7 Å is preferred for 45 nm node DRAM devices.

With continued reference to FIG. 6, AlOₓ (Al₂O₃ in the embodiment of FIG. 5) is next deposited 58 onto the substrate without changing the temperature in the deposition chamber, preferably by multiple cycles of an ALD process. For example, AlOₓ can be formed by alternately pulsing ozone (or another suitable oxygen precursor) and TMA. The AlOₓ can form, e.g., the layer 50 of FIG. 5. Advantageously, the aforementioned cyclopentadienyl precursors make it possible to deposit the Zr/Hf oxide in step 56 at substantially the same temperature (e.g., about 300° C.) as the AlOₓ deposition in step 58. Next, ZrOₓ or HfOₓ (ZrO₂ or HfO₂ in the embodiment of FIG. 5) is again deposited 60 onto the substrate without changing the temperature of the deposition chamber, preferably by multiple cycles of an ALD process using a cyclopentadienyl precursor. The same precursors used in step 56 can be employed for step 60. This Zr/Hf oxide can form, e.g., the layer 52 of FIG. 5. Finally, the substrate is unloaded 62 from the deposition chamber. As noted above, these deposition steps are conducted in situ, without removing the substrates from the chamber between said deposition steps. By depositing both the Zr/Hf oxide and aluminum oxide films in the same reaction chamber, it is possible to avoid the formation of an undesired interface between the Zr/Hf oxide and the aluminum oxide. The elimination of one reactor reduces costs. Also, the elimination of the intermediate substrate transfer step simplifies the processing logistics and increases substrate throughput. Moreover, isothermal processing maintains purity by avoiding CTE mismatch issues raised by in situ deposition of multiple different layers accompanied by temperature changes.

### Batch Reactor

As mentioned above, the in situ deposition of Zr/Hf oxide and aluminum oxide films is preferably conducted on a plurality of substrates, such as semiconductor wafers, in a batch reactor. Several exemplary batch reactors are now described.

Preferably, the batch reactor includes valves connected to controllers configured or programmed to deliver one or more reactants in temporally separated pulses. The batch reactor preferably has a vertically extending reaction chamber that accommodates substrates vertically separated from each other, with major faces of the substrates oriented horizontally. Preferably, the reaction chamber accommodates at least 25 substrates, and more preferably at least 50 substrates.

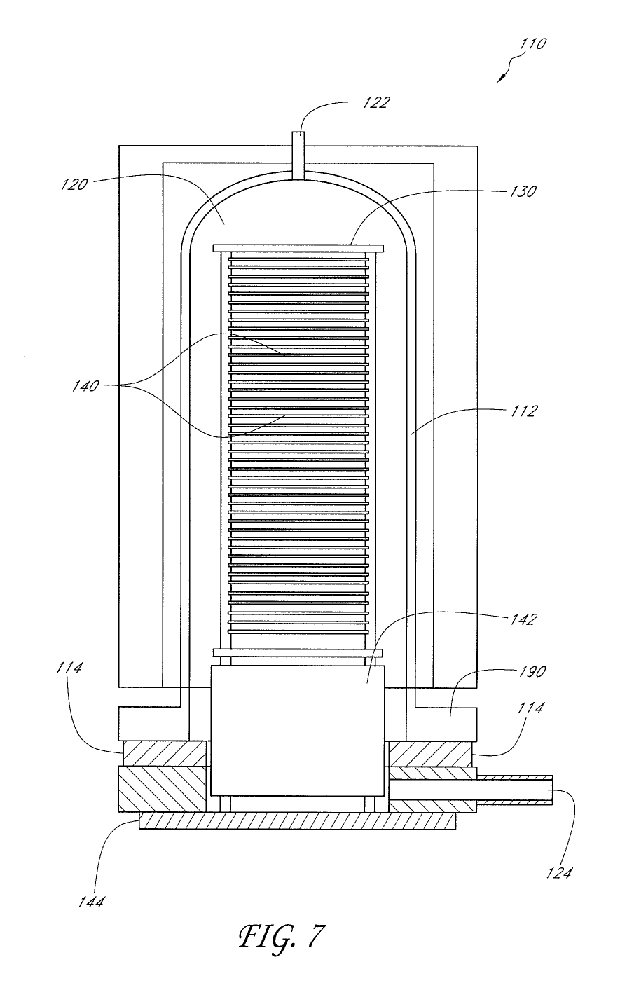

FIG. 7 schematically shows a vertical furnace reactor 110 that accommodates substrates 140 vertically separated from one another, and which has benefits for efficient heating and loading sequences. The furnace 110 is preferably adapted to support 100-125 substrates. Examples of suitable vertical furnaces are the A400™ and A412™ vertical furnaces, commercially available from ASM International, N.V. of Bilthoven, the Netherlands. A vertical furnace type of reactor has benefits for efficient heating and loading sequences. It will be understood, however, that while preferred embodiments are presented in the context of a vertical batch furnace, the principles and advantages disclosed herein will have application to other types of reactors. For example, while the illustrated reactors are shown holding substrates in a vertically-separated manner, the methods described herein can be applied to a batch reactor that holds substrates in a horizontally separated manner.

With continued reference to FIG. 7, a tube 112 defines a reaction chamber 120 in the interior of the vertical furnace or reactor 110. The lower end of the tube 112 terminates in a flange 190, which mechanically seals the chamber 120 by contact with a lower support surface 114. Process gases can be fed into the reaction chamber 120 through a gas inlet 122 at the top of the chamber 120 and evacuated out of the chamber 120 through a gas outlet 124 at the bottom of the chamber 120. The reaction chamber 120 accommodates a wafer boat 130 holding a stack of vertically spaced substrates or wafers 140.

The process tube flange 190 can be maintained at an elevated temperature to avoid condensation of process gases on it. It will be appreciated that the elevated temperature can vary from process to process and is preferably chosen based upon the identities of the process gases. As noted above, in certain embodiments the process gases are O₃, TMA, and at least one of (MeCp)₂Zr(OMe)₂, (MeCp)₂Zr(OMe)Me, (MeCp)₂Hf(OMe)₂, and (MeCp)₂Hf(OMe)Me. For example, the elevated temperature of the flange 190 is preferably above 120° C., preferably about 180-200° C. Regulation of the temperature of the flange 190 can be achieved by providing it with electrical heaters and a water-cooling system. The water-cooling is desired primarily to avoid overheating of the flange 190 during unloading of a batch of hot wafers 140.

Various systems can be used to supply reactants or precursors to the reaction chamber 120 (FIG. 7). For example, where the precursor is a gas under standard conditions, it can be flowed directly from a gas source to the chamber 120. The timing and rate of the flow of the gas can be controlled by, e.g., valves and mass flow controllers, as known in the art.

Each of the four aforementioned cyclopentadienyl precursors, (MeCp)₂Zr(OMe)₂, (MeCp)₂Zr(OMe)Me, (MeCp)₂Hf(OMe)₂, and (MeCp)₂Hf(OMe)Me, is stored as a liquid. TMA is also stored as a liquid. For these and other liquid precursor sources, a vaporizer such as a bubbler can be used to supply the precursor to the chamber 120 in gaseous form. The timing and rate of flow of such a precursor can be regulated by controlling the flow of carrier gas through the liquid in the bubbler and by controlling the temperature of the liquid. It will be appreciated that the quantity of the liquid precursor carried by the carrier gas increases with increasing temperature.

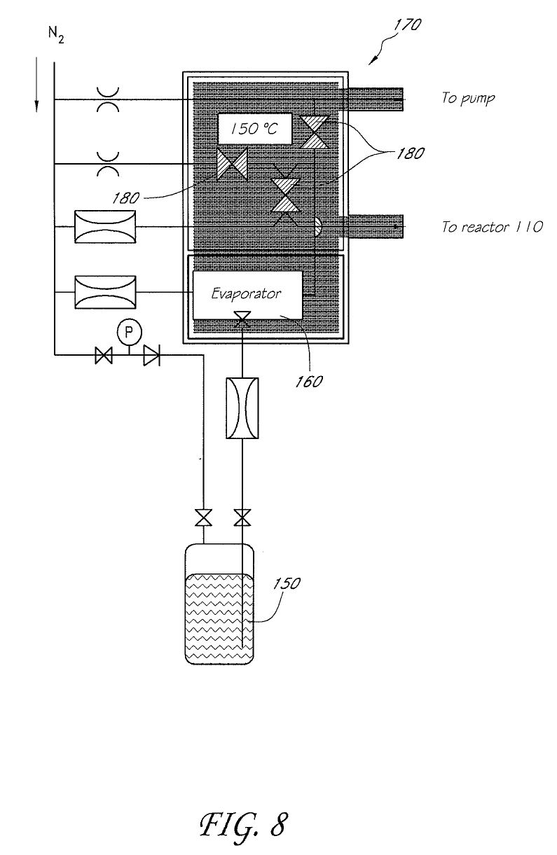

FIG. 8 schematically shows another exemplary system for controlling the delivery of vapor from liquid precursors. The liquid precursor is stored in a container 150. Liquid flow control is used to regulate the amount of the precursor flowing into the reactor 110 by regulating the flow of the liquid into an evaporator or vaporizer 160. After being vaporized, well-separated pulses of a precursor can be generated and flowed into the reaction chamber 120 using a valve system 170 comprising valves 180, shown in the upper section of FIG. 8. Preferably, the valves 180 of the valve system 170 are operated at elevated temperatures and have no or minimal dead volume, to provide good separation between the flow of different reactants. Such a valve system is described in further detail in U.S. Patent Application Publication No. US 2004/0250853 A1.

As noted above, process gases can be introduced into the chamber 20 in various ways. For example, in the reactor illustrated in FIG. 7, all gases are introduced into the interior 120 of the reactor 110 at the top, via the top inlet 122, and exhausted at the bottom of the reactor 110, via the exhaust 124. In other embodiments, a more even distribution of the process gases can be achieved over the length of the tube by using multiple-hole injectors for introduction of process gases into the reactor. Suitable multiple-hole injectors are disclosed in U.S. Pat. No. 6,746,240, and U.S. Patent Application Publication No. US 2003/0111013 A1. Alternatively, less spacious and cylindrical multiple-hole injectors can be used. Such injectors can have, e.g., a diameter of about 25 mm and holes of about 1 mm diameter. In some embodiments, multiple-hole injectors are mounted on or beneath the flange 190 at the lower end of the reaction chamber 120 and point upwardly.

A multiple-hole injector is preferably not used to introduce a purge gas, however, because the top part of the reaction chamber 120 may be not effectively purged by an injector that only extends part way up the height of the chamber 120. Preferably, a purge gas is introduced into the chamber 120 at the chamber end that is opposite to the exhaust end, so that the purge gas flows through all regions of the reaction chamber 120 after entry and before being exhausted.

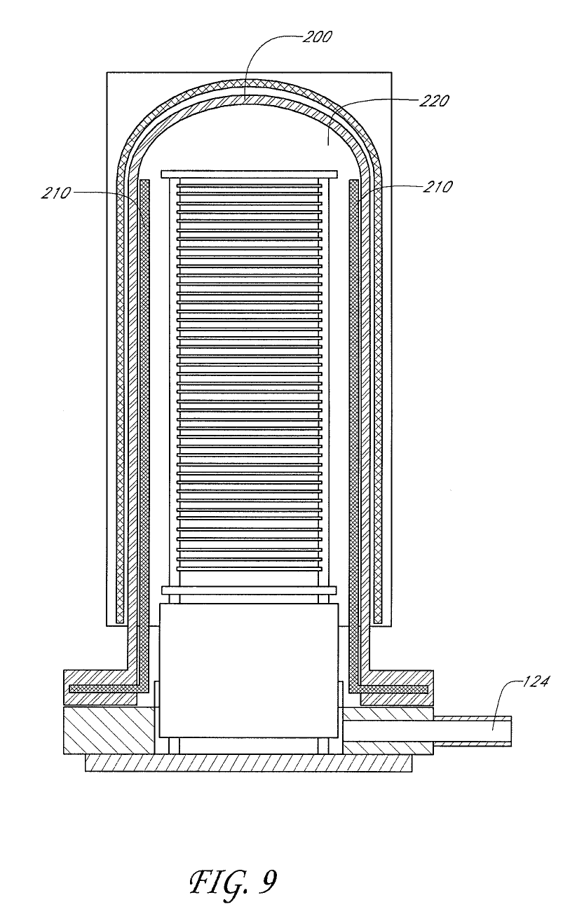

FIG. 9 shows another exemplary batch reactor. In this design, the process tube 200 is closed at the top. An advantage of this design is that the process tube 200 is simpler in construction and issues with the gas-tightness and the thermal isolation of the top inlet 122 (FIG. 7) can be avoided. All gases in this set-up are introduced through gas injectors 210, of which two are shown. Preferably, separate injectors 210 are used for each reactant in an ALD process. In the case of Zr/Hf oxide deposition, one injector 210 can be used for the Zr/Hf precursor vapor (such as one of the four above-mentioned cyclopentadienyl Zr/Hf precursors), and another injector 210 can be used for the oxygen precursor vapor (such as O₃). An additional injector 210 can be provided for the aluminum precursor vapor (such as TMA). It will be understood that a process tube 200 designed for in situ deposition of Zr/Hf oxide and aluminum oxide may include just three injectors 210 for the deposition steps—one for the appropriate cyclopentadienyl Zr/Hf precursor, one for TMA, and one for the oxygen precursor. These injectors 210 are preferably multiple-hole gas injectors having holes distributed over the height of the tube 200. The injectors 210 may be each oriented substantially perpendicular to the substrates. Each injector 210 may extend along a majority of a length of the arrangement of substrates. An exhaust 124 is provided, preferably at the bottom of the tube 200, for process gases exiting the tube 200.

An additional injector can be used for a purge gas, preferably an inert gas such as nitrogen gas. The injector for the purge gas is preferably a tube with an open end at the top and without gas discharge holes in its sidewall, so that all the purge gas is discharged at the top of the reaction chamber 220.

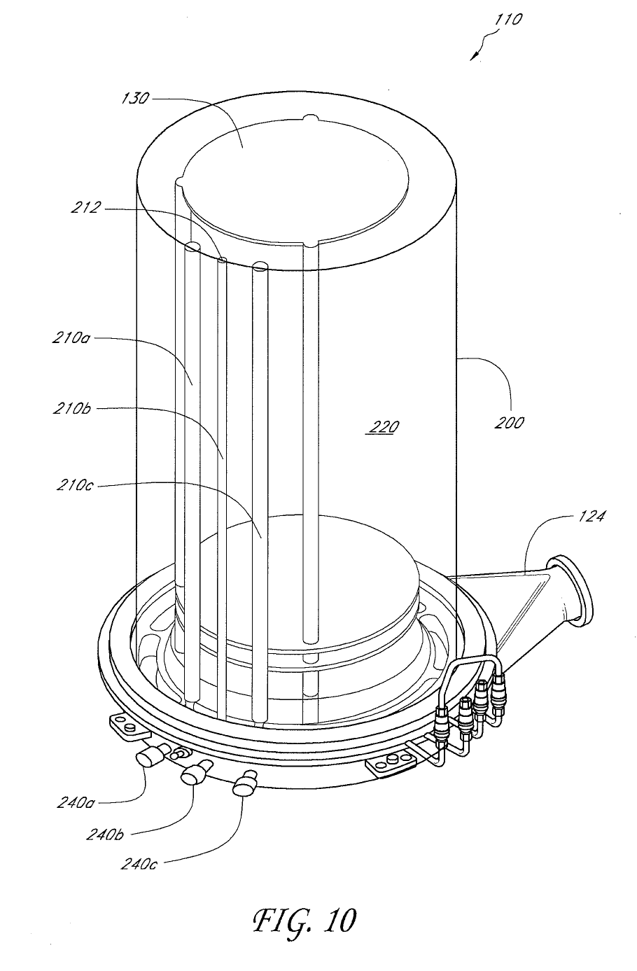

FIG. 10 illustrates a reactor 110 having three vertically extending injectors, 210a, 210b and 210c. The injectors 210a, 210b and 210c each have an inlet 240a, 240b, and 240c, respectively, for connecting to one or more gas feeds. The injector 210b opens at its top end 212 to allow purge gas to flow downward through the reactor 110 and to exit out the exhaust 124 at the bottom of the reactor 110. In other embodiments, the exhaust 124 can be at the top of the reaction chamber 220 and the purge gas can be discharged at the bottom of the reaction chamber 220. Advantageously, the injectors are multiple-hole gas injectors, such that the evenness of gas distribution into the reaction chamber can be improved, thereby improving the uniformity of deposition results.

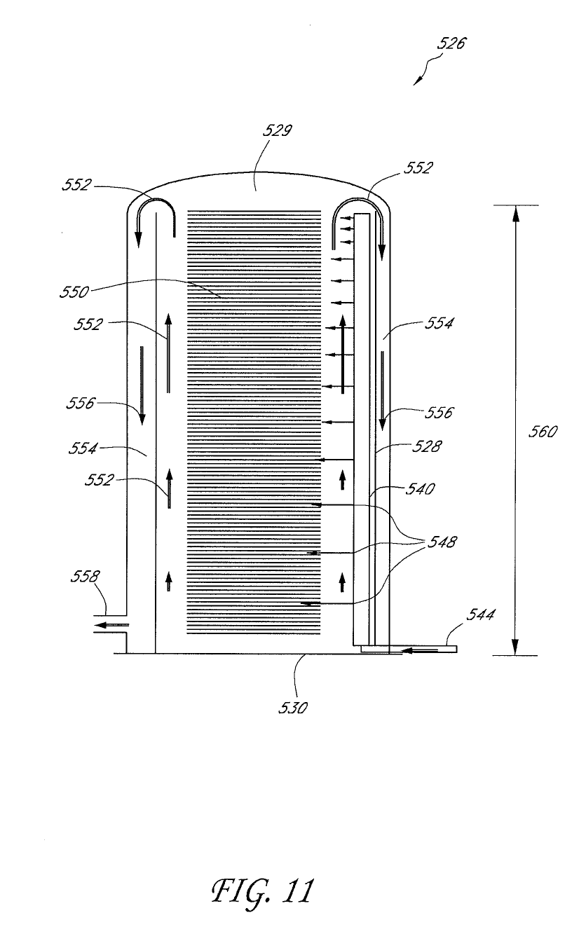

FIGS. 11-13 illustrate another version of an exemplary batch reactor, also commercially available under the trade name Advanced 412™ or A412™ from ASM International N.V. of Bilthoven, The Netherlands. FIG. 11 is a schematic cross-sectional side-view of the elongated furnace with a gas injector. The process tube or chamber 526 is preferably surrounded by a heating element (not shown). A liner 528, delimiting the outer perimeter of the reaction space 529, is preferably provided inside the process chamber 526. Preferably, at the bottom of the process chamber 526, a wafer load 550 may enter and exit the process chamber 526 by a door 530. Precursor source gas is injected through a gas injector 540, preferably via a gas feed conduit 544. The gas injector 540 is provided with a pattern of holes 548, preferably extending substantially over the height of the wafer load 550. Note that, because gases are first introduced into the reaction space 529 from the holes 548 of the gas injector 540, the interior of gas delivery devices through which gases travel, such as the gas injector 540, is not part of the reaction space 529 and is, in a sense, outside of the reaction space 529. Consequently, the reaction space 529 comprises the interior volume of the process chamber 526, excluding the volume occupied by gas delivery devices such as the gas injector 540. Further details of the chamber 526 are provided in U.S. Patent Application Publication No. US 2003/0111013 A1.

In a preferred embodiment, inside the process chamber 526, gas is flowed in a generally upward direction 552 and then removed from the reaction space 529 via an exhaust space 554 between the process chamber 526 and the liner 528, where gas flows in a downward direction 556 to the exhaust 558, which may be connected to a pump (not shown). The gas injector 540 preferably distributes process gases inside the process chamber 526 over the entire height of the reaction space 529. The gas injector 540 itself acts as a restriction on the flow of gas, such that the holes 548 that are closer to the conduit 544 tend to inject more gas into the reaction space than those holes 548 that are farther from the conduit 544. Preferably, this tendency for differences in gas flows through the holes 548 can be compensated to an extent by reducing the distance between the holes 548 (i.e., increasing the density of the holes 548) as they are located farther away from the conduit 544. In other embodiments, the size of individual holes making up the holes 548 can increase with increasing distance from the conduit 544, or both the size of the holes 548 can increase and also the distance between the holes 548 can decrease with increasing distance from the conduit 544. Advantageously, however, the preferred embodiments are illustrated with holes 548 of constant size so as to minimize the surface area of the sides of the gas injector 540 containing the holes 548.

The injector 540 is advantageously designed to reduce the pressure inside the gas injector, resulting in a reduction of the gas phase reactions within the injector, since reaction rates typically increase with increasing pressure. While such reduced pressure can also lead to a poor distribution of gas over the height of the gas injector 540, the distribution of holes 548 across the height of the injector 540 is selected to improve uniformity of gas distribution.

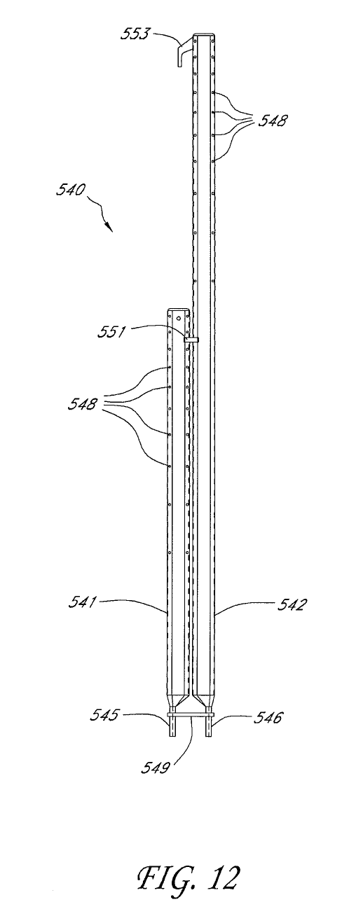

FIG. 12 shows one illustrative embodiment of the gas injector 540 of FIG. 11. The gas injector 540 preferably comprises two gas injector parts 541 and 542, each preferably provided with separate gas feed conduit connections 545 and 546, respectively. The first part 541 injects gas into the lower volume of the reaction space 529 (FIG. 11) and the second part 542 injects gas into the upper volume of the reaction space 529. The parts 541 and 542 are connected by linkages 549 and 551. At its top end, the gas injector 540 can be provided with a hook 553, to secure the top end of the gas injector 540 to a hook support inside the chamber 526 (FIG. 11).

The gas injector 540 is provided with a pattern of holes 548 substantially extending over the height 560 (FIG. 11) of the wafer load 550. The total cross section of the holes is preferably at least about 30 mm². The diameter of each of holes 548 is preferably about 1 mm or more, more preferably between about 2.5 mm and 3.5 mm, and in one embodiment about 3 mm. In the illustrative embodiment shown in FIG. 12, the gas injector 540 has a total of 40 holes 548 for a total hole cross-sectional area of about 282 mm². More generally, the total cross-sectional area of the holes 548 is preferably about 30 mm² or more, and more preferably between about 196 mm² and 385 mm².

Advantageously, the use of two gas injector parts 541 and 542 allows for further tuning possibilities. The flows supplied to the different gas injector parts 541, 542 can be chosen differently to fine-tune the gas flow into the reaction space 529. This will improve uniformity in the deposition rates of precursors over the height 560 of the wafer load 550 (FIG. 11).

One skilled in the art will appreciate that further modifications to the batch reactor, or to the way of operating the batch reactor, known in the art, can be applied to improve the performance of this process. For example, it is possible to use a holder boat or ring boat (i.e., a wafer boat in which each wafer is individually supported by a separate wafer holder or ring-shaped holder inserted into the boat).

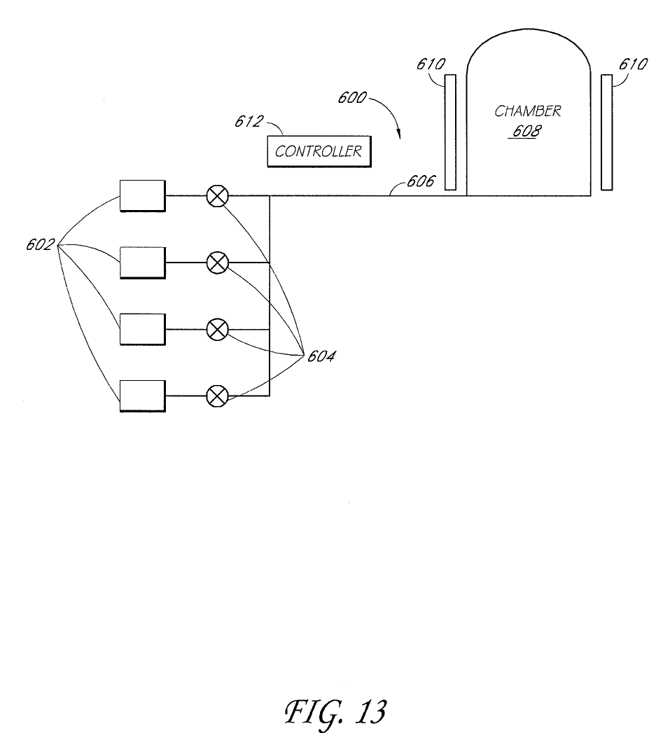

FIG. 13 illustrates an embodiment of a deposition apparatus comprising a deposition control system 600 that is configured to control the temperature of a deposition chamber 608 and the flow of gases through the chamber 608. The apparatus includes a plurality of reactant sources 602 (such as those described above), a valve system 604, a gas flow network 606 (e.g., pipes and an injector) for delivering gases into the chamber 608, one or more heating elements 610 for heating the chamber 608, and a controller 612. The valve system 604 preferably includes at least one separate valve for each reactant source 602, for controlling that particular reactant gas flow through the network 606. Preferably, the gas flow network 606 maintains separate flow paths into the chamber 608 for each ALD reactant. Carrier and purge gas sources (they can be the same gas in some embodiments) and associated valves can also be provided. The chamber 608 can be one of the above-described batch reactors. Alternatively, the chamber 608 can be a single substrate reactor. The heating elements 610 can be resistive heaters or radiant heat lamps, or even a combination thereof, as disclosed, for example, in U.S. Patent Application Publication No. US 2008/0081112 A1.

The controller 612 is preferably configured to control the valve system 604 to deliver the reactant, purge, and carrier gases into the chamber 608 in accordance with the preferred process recipes, as described above. The controller 612 is preferably also configured to control power to the heating elements 610 to set a desired temperature inside the chamber 608, in conjunction with feedback from temperature sensors that measure the temperature. The controller 612 is preferably configured to adjust the power to the heating elements 610 during processing to maintain the desired temperature of substrates within the chamber 608. Thus, the controller 612 preferably allows the deposition control system 600 to control the valve system 604 and the temperature inside the chamber 608. The deposition control system 600 can be programmed to deliver the reactant vapors of a given process recipe (including the multiple in situ ALD processes described above) into the chamber while maintaining chamber temperatures preferably within about 25° C., more preferably within about 10° C., and even more preferably within about 5° C. of one another throughout the in situ deposition steps. The deposition control system 600 can also be programmed to conduct multiple, in situ ALD steps at chamber temperatures within about 300-500° C. Moreover, the temperature range of 300-350° C. is of particular interest for the reactions described above.

### EXAMPLE

The following represents process conditions in one example of in situ deposition of a ZrOₓ/AlOₓ/ZrOₓ stack, also referred to herein as ZAZ, onto a plurality of semiconductors in a batch reaction chamber. The first layer is a ZrOₓ film with a target thickness of 32 Å. The second layer is an AlOₓ film (such as Al₂O₃) with a target thickness of 3-4 Å. The third layer is another ZrOₓ film with a target thickness of 32 Å. For pulsed ALD deposition, temperature in the reaction chamber is set to about 300° C., and pressure is set to about 200 mTorr. The zirconium precursor is (MeCp)₂Zr(OMe)Me, the aluminum precursor is TMA, and the oxygen precursor is O₃. The zirconium and aluminum precursor sources are stored as liquids. The carrier/purge gas is N₂.

The three layers are grown according to the following process recipe: The first zirconium oxide film is grown using 43 cycles of the following sequence: ozone pulse, purge, zirconium precursor pulse, and purge. The aluminum oxide film is then grown using 4 cycles of the following sequence: ozone pulse, purge, TMA pulse, and purge. Finally, the second zirconium oxide film is grown using 43 cycles of the following sequence: ozone pulse, purge, zirconium precursor pulse, and purge. The flow rate of the zirconium precursor in this process recipe is about 0.15 g/min, and the flow rate of the TMA is about 0.7 g/min. The ozone gas is injected at a flow rate of about 3 slm. The flow rate of the N₂ carrier gas is about 1 slm.

Although this invention has been disclosed in the context of certain preferred embodiments and examples, it will be understood by those skilled in the art that the present invention extends beyond the specifically disclosed embodiments to other alternative embodiments and/or uses of the invention and obvious modifications and equivalents thereof. Further, the various features of this invention can be used alone, or in combination with other features of this invention other than as expressly described above. Thus, it is intended that the scope of the present invention herein disclosed should not be limited by the particular disclosed embodiments described above, but should be determined only by a fair reading of the claims that follow.

What is claimed is:

1. A method of depositing multiple layers of different materials in a sequential process within a deposition chamber, the method comprising:
providing a substrate in a deposition chamber;
sequentially conducting a plurality of cycles of a first atomic layer deposition (ALD) process to deposit a layer of a first material on the substrate in the deposition chamber, the first cycles including pulsing a cyclopentadienyl metal precursor; and
sequentially conducting a plurality of cycles of a second ALD process to deposit a layer of a second material on the layer of the first material in the deposition chamber, wherein the second material comprises a metal different from the metal in the cyclopentadienyl metal precursor.

2. The method of claim 1, wherein the first and second materials comprise metal oxide materials.

3. The method of claim 2, wherein the first material comprises zirconium oxide or hafnium oxide, and the second material comprises aluminum oxide.

4. The method of claim 1, further comprising conducting a further plurality of cycles of the first ALD process within the deposition chamber to deposit a second layer of the first material over the layer of the second material.

5. The method of claim 1, wherein the cycles of the first ALD process are conducted at a first average temperature and the cycles of the second ALD process are conducted at a second average temperature, the first and second temperatures being within about 25° C. of one another.

6. The method of claim 5, wherein the first and second temperatures are within about 10° C. of one another.

7. The method of claim 5, wherein the deposition chamber comprises a batch vertical furnace housing a plurality of substrates, wherein providing the substrate comprises loading a plurality of substrates into the deposition chamber, and sequentially conducting the pluralities of the first and second ALD processes comprises depositing the layers of the first and second materials on the plurality of substrates.

8. The method of claim 1, wherein the cyclopentadienyl metal precursor comprises a precursor selected from the group consisting of bis(cyclopentadienyl)bis(methoxy) hafnium (IV), bis(cyclopentadienyl)methyl methoxy hafnium (IV), bis(methylcyclopentadienyl)bis(methoxy) hafnium (IV), bis(methylcyclopentadienyl)methyl methoxy hafnium (IV), bis(cyclopentadienyl)bis(methoxy) zirconium (IV), bis(cyclopentadienyl)methyl methoxy zirconium (IV), bis(methylcyclopentadienyl)bis(methoxy) zirconium (IV), and bis(methylcyclopentadienyl)methyl methoxy zirconium (IV).

9. The method of claim 1, wherein the first material comprises zirconium oxide or hafnium oxide, and the second material comprises aluminum oxide, the method further comprising sequentially conducting another plurality of cycles of the first ALD process to deposit an additional layer of zirconium oxide or hafnium oxide over the layer of aluminum oxide within the deposition chamber

10. The method of claim 9, wherein sequentially conducting the plurality of cycles of the second ALD process comprises pulsing trimethyl aluminum.

11. The method of claim 9, wherein sequentially conducting pluralities of each of the first and second ALD processes comprises maintaining the substrate at a temperature between about 300° C. and 500° C.

12. An apparatus comprising:
a processing chamber configured to contain a plurality of substrates;
a cyclopentadienyl metal precursor source connected to the chamber to deliver a vapor of the cyclopentadienyl metal precursor into the chamber;
an oxygen precursor source connected to the chamber to deliver a vapor of the oxygen precursor into the chamber;
an aluminum precursor source connected to the chamber to deliver a vapor of the aluminum precursor into the chamber; and
a deposition control system configured to conduct ALD in the chamber of a metal oxide from the cyclopentadienyl metal precursor and the oxygen precursor, the deposition control system also configured to conduct ALD in the chamber of aluminum oxide from the aluminum precursor and the oxygen precursor.

13. The apparatus of claim 12, wherein the cyclopentadienyl metal precursor comprises a precursor selected from the group consisting of bis(cyclopentadienyl)bis(methoxy)hafiiium (IV), bis(cyclopentadienyl)methyl methoxy hafnium (IV), bis(methylcyclopentadienyl)bis(methoxy)hafiium (IV), bis(methylcyclopentadienyl)methyl methoxy hafnium (IV), bis(cyclopentadienyl)bis(methoxy) zirconium (IV), bis(cyclopentadienyl)methyl methoxy zirconium (IV), bis(methylcyclopentadienyl)bis(methoxy) zirconium (IV), and bis(methylcyclopentadienyl)methyl methoxy zirconium (IV).

14. The apparatus of claim 12, wherein the oxygen precursor comprises ozone (O₃), H₂O, or O₂.

15. The apparatus of claim 12, wherein the aluminum precursor comprises trimethyl aluminum (TMA).

16. The apparatus of claim 12, wherein the deposition control system is programmed to control the chamber temperature and to conduct the ALD of the metal oxide and the aluminum oxide at chamber temperatures within about 25° C. of one another.

17. The apparatus of claim 12, wherein the deposition control system is programmed to control the chamber temperature and to conduct the ALD of the metal oxide and the aluminum oxide at chamber temperatures within about 300-500° C.

18. The apparatus of claim 17, wherein the deposition control system is programmed to conduct the ALD of the metal oxide and the aluminum oxide at temperatures within about 300-350° C.

19. An apparatus comprising:
a processing chamber configured to contain a plurality of substrates;
a first reactant source connected to the chamber to deliver a vapor of the first reactant into the chamber, the first reactant comprising a cyclopentadienyl metal precursor;
a second reactant source connected to the chamber to deliver a vapor of the second reactant into the chamber, the second reactant comprising a metal different from the metal in the cyclopentadienyl metal precursor; and
a deposition control system configured to conduct a first ALD process in the chamber of a first metallic layer from the cyclopentadienyl metal precursor, the deposition control system also configured to conduct a second ALD process in the chamber of a second metallic layer from the second reactant, the deposition control system configured to conduct the first and second ALD processes at temperatures within about 25° C. of one another.

20. The apparatus of claim 19, wherein the deposition control system is configured to conduct the first and second ALD processes at temperatures within about 10° C. of one another.

21. The apparatus of claim 19, wherein the deposition control system is configured to conduct the first and second ALD processes at temperatures within about 5° C. of one another.

22. The apparatus of claim 19, wherein the cyclopentadienyl metal precursor comprises a precursor selected from the group consisting of bis(cyclopentadienyl)bis(methoxy) hafnium (IV), bis(cyclopentadienyl)methyl methoxy hafnium (IV), bis(methylcyclopentadienyl)bis(methoxy) hafnium (IV), bis(methylcyclopentadienyl)methyl methoxy hafnium (IV), bis(cyclopentadienyl)bis(methoxy) zirconium (IV), bis(cyclopentadienyl)methyl methoxy zirconium (IV), bis(methylcyclopentadienyl)bis(methoxy) zirconium (IV), and bis(methylcyclopentadienyl)methyl methoxy zirconium (IV).
